(19) United States
(12) Patent Application Publication
(10) Pub. No.: US 2016/0260734 A1
(43) Pub. Date: Sep. 8, 2016

(54) SEMICONDUCTOR DEVICE AND METHOD OF MANUFACTURING THE SAME

(71) Applicant: KABUSHIKI KAISHA TOSHIBA, Minato-ku (JP)

(72) Inventors: Takayuki BEPPU, Yokkaichi (JP); Kazuaki NAKAJIMA, Yokkaichi (JP); Seiichi OMOTO, Yokkaichi (JP)

(73) Assignee: KABUSHIKI KAISHA TOSHIBA, Minato-ku (JP)

(21) Appl. No.: 14/789,081

(22) Filed: Jul. 1, 2015

Related U.S. Application Data
(60) Provisional application No. 62/129,436, filed on Mar. 6, 2015.

(51) Int. Cl. H01L 27/115

(52) U.S. Cl. CPC H01L 27/11582

(57) ABSTRACT

In one embodiment, a semiconductor device includes a substrate, a semiconductor layer provided on the substrate, and plural insulators and plural interconnects alternately provided on a side face of the semiconductor layer. Each of the interconnects includes a first interconnect layer provided on the side face of the semiconductor layer, and having an upper face that is in contact with one of the insulators and a lower face that is in contact with one of the insulators. Each of the interconnects further includes a second interconnect layer provided on a side face of the first interconnect layer, and having an upper face that is in contact with one of the insulators and a lower face that is in contact with one of the insulators.

### CROSS REFERENCE TO RELATED APPLICATION

This application is based upon and claims the benefit of priority from the prior U.S. Provisional Patent Application No. 62/129,436 filed on Mar. 6, 2015, the entire contents of which are incorporated herein by reference.

### FIELD

Embodiments described herein relate to a semiconductor device and a method of manufacturing the same.

### BACKGROUND

For example, a three-dimensional memory has a structure where plural insulators and plural interconnects are alternately stacked on a substrate. Such a stacked structure can be formed by alternately stacking the plural insulators and plural sacrificial films on the substrate and replacing the sacrificial films with the plural interconnects. For example, each interconnect contains a barrier metal layer such as a titanium nitride (TiN) layer and an interconnect material layer such as a tungsten (W) layer.

In the future, if the number of layers in the stacked structure becomes larger, it is required to reduce the vertical thickness of each interconnect (each sacrificial film) to suppress the increase of the vertical thickness of the three-dimensional memory. However, if the vertical thickness of each interconnect is reduced, the ratio of the barrier metal layer in each interconnect becomes higher, which increases the resistance of the interconnects.

### BRIEF DESCRIPTION OF THE DRAWINGS

FIGS. 1 and 2 are cross sectional views showing a structure of a semiconductor device of a first embodiment;

FIG. 3 is a cross sectional view showing a structure of a semiconductor device of a comparative example of the first embodiment;

FIGS. 4A to 9B are cross sectional views showing a method of manufacturing the semiconductor device of the first embodiment;

FIG. 10 is a cross sectional view showing a method of manufacturing a semiconductor device of a modification of the first embodiment; and

FIGS. 11A and 11B are cross sectional views showing a method of manufacturing the semiconductor device of the comparative example of the first embodiment.

### DETAILED DESCRIPTION

Embodiments will now be explained with reference to the accompanying drawings.

In one embodiment, a semiconductor device includes a substrate, a semiconductor layer provided on the substrate, and plural insulators and plural interconnects alternately provided on a side face of the semiconductor layer. Each of the interconnects includes a first interconnect layer provided on the side face of the semiconductor layer, and having an upper face that is in contact with one of the insulators and a lower face that is in contact with one of the insulators. Each of the interconnects further includes a second interconnect layer provided on a side face of the first interconnect layer, and having an upper face that is in contact with one of the insulators and a lower face that is in contact with one of the insulators.

### First Embodiment

### (1) Structure of Semiconductor Device of First Embodiment

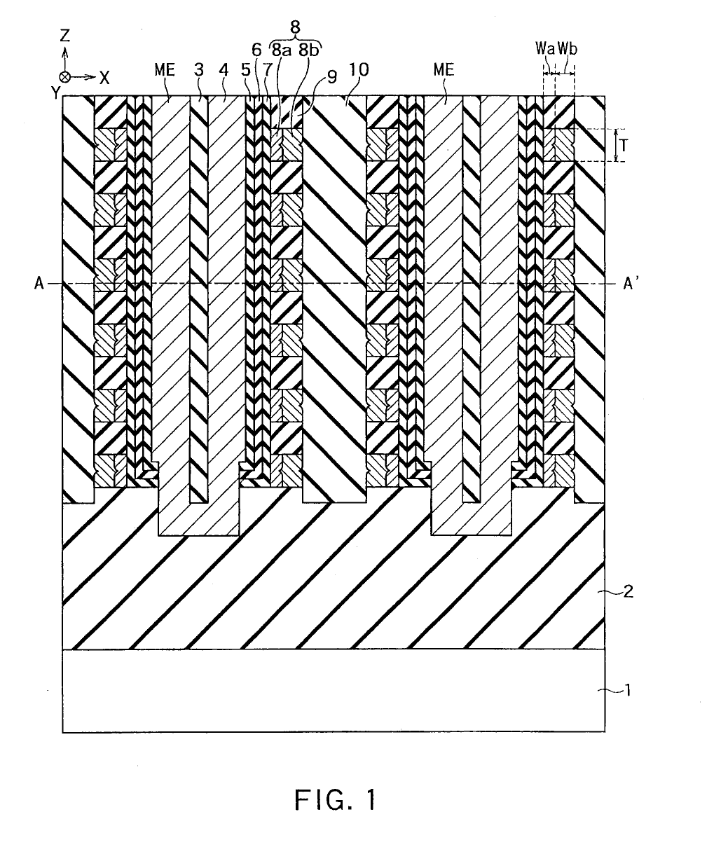

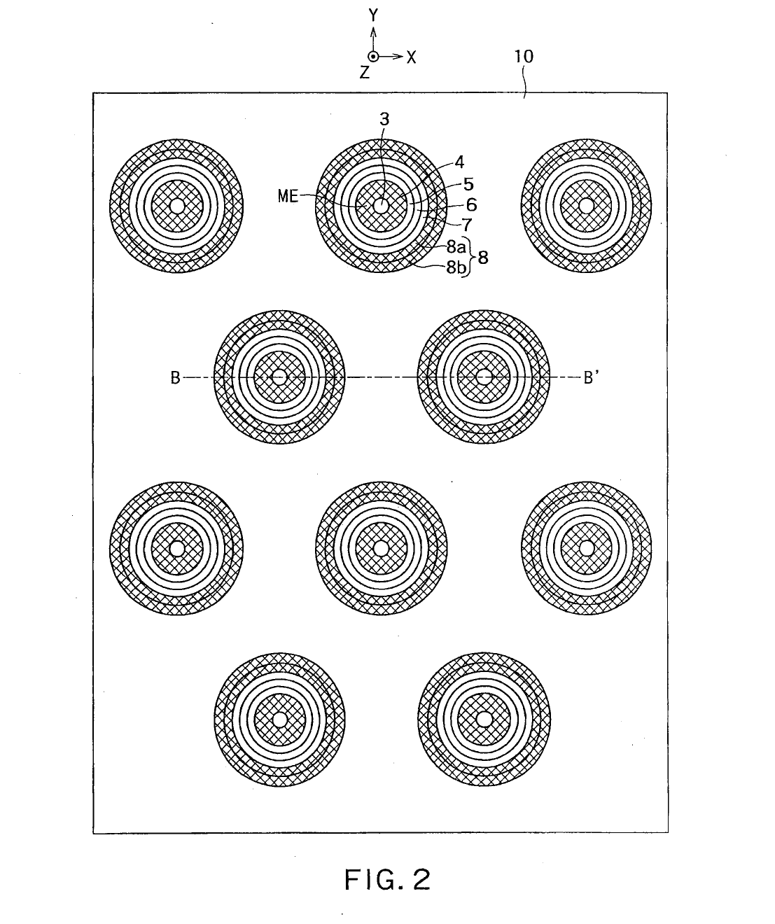

FIGS. 1 and 2 are cross sectional views showing a structure of a semiconductor device of a first embodiment. FIG. 2 shows a cross section taken along a line A-A′ in FIG. 1. FIG. 1 shows a cross section taken along a line B-B′ in FIG. 2.

The semiconductor device in the present embodiment includes, as a three-dimensional memory, a stacked NAND flash memory. FIG. 1 shows two memory elements ME in this memory. FIG. 2 shows ten memory elements ME in this memory.

The semiconductor device in the present embodiment includes a substrate 1 and an inter layer dielectric 2. The semiconductor device in the present embodiment further includes, for each memory element ME, a first memory insulator 3, a semiconductor layer 4, a second memory insulator 5, a charge storing layer 6, a third memory insulator 7, plural interconnects 8 and plural insulators 9. The second and third memory insulators 5 and 7 are examples of first and second insulators of the disclosure. The interconnects 8 are an example of plural interconnects of the disclosure. The insulators 9 are an example of plural insulators of the disclosure. The inter layer dielectric 2 in the vicinity of the lowermost interconnect 8 is also an example of the plural insulators of the disclosure. The semiconductor device in the present embodiment further includes an inter layer dielectric 10.

The structure of the semiconductor device in the present embodiment will be described below mainly with reference to FIG. 1. In this description, FIG. 2 is also referred to as appropriate.

An example of the substrate 1 is a semiconductor substrate such as a silicon substrate. FIG. 1 shows an X direction and a Y direction that are parallel to the surface of the substrate 1 and perpendicular to each other, and a Z direction that is perpendicular to the surface of the substrate 1. In the present specification, the +Z direction is treated as an upward direction, and the −Z direction is treated as a downward direction. For example, the positional relationship between the substrate 1 and the inter layer dielectric 2 is expressed that the substrate 1 is positioned below the inter layer dielectric 2. The −Z direction in the present embodiment may be identical to a gravity direction or may not be identical to the gravity direction.

The inter layer dielectric 2 is formed on the substrate 1. An example of the inter layer dielectric 2 is a silicon oxide film. The inter layer dielectric 2 may be a stacked film including plural insulators. The inter layer dielectric 2 may be directly formed on the substrate 1 or may be formed on the substrate 1 through another layer.

The first memory insulator 3 is formed on the inter layer dielectric 2 through the semiconductor layer 4. The first memory insulator 3 has a cylindrical shape extending in the Z direction. Therefore, as shown in FIG. 2, the planar shape of the first memory insulator 3 is a round shape. An example of the first memory insulator 3 is a silicon oxide film.

The semiconductor layer 4 is formed on the inter layer dielectric 2 and in contact with the side face and the lower face of the first memory insulator 3. The semiconductor layer 4 has a tubular shape extending in the Z direction around the first memory insulator 3, except for a portion in the vicinity of the lower face of the first memory insulator 3. Therefore, as shown in FIG. 2, the planer shape of the semiconductor layer 4 is a round annular shape that surrounds the first memory insulator 3. An example of the semiconductor layer 4 is a monocrystalline silicon layer. The semiconductor layer 4 functions as a channel semiconductor layer of each memory element ME.

The second memory insulator 5 is formed on the inter layer dielectric 2 and in contact with the side face of the semiconductor layer 4. The second memory insulator 5 has a tubular shape extending in the Z direction around the semiconductor layer 4. Therefore, as shown in FIG. 2, the planar shape of the second memory insulator 5 is a round annular shape that surrounds the semiconductor layer 4. An example of the second memory insulator 5 is a silicon oxide film. The second memory insulator 5 functions as a tunnel insulator of each memory element ME.

The charge storing layer 6 is formed on the inter layer dielectric 2 and in contact with the side face of the second memory insulator 5. The charge storing layer 6 has a tubular shape extending in the Z direction around the second memory insulator 5. Therefore, as shown in FIG. 2, the planar shape of the charge storing layer 6 is a round annular shape that surrounds the second memory insulator 5. An example of the charge storing layer 6 is a silicon nitride film or a polycrystalline silicon layer.

The third memory insulator 7 is formed on the inter layer dielectric 2 and in contact with the side face of the charge storing layer 6. The third memory insulator 7 has a tubular shape extending in the Z direction around the charge storing layer 6. Therefore, as shown in FIG. 2, the planar shape of the third memory insulator 7 is a round annular shape that surrounds the charge storing layer 6. An example of the third memory insulator 7 is a silicon oxynitride film. The third memory insulator 7 functions as a charge blocking layer of each memory element ME.

The interconnects 8 and the insulators 9 are alternately stacked on the inter layer dielectric 2 and in contact with the side face of the third memory insulator 7. As shown in FIG. 2, the planar shapes of the interconnects 8 are round annular shapes that surround the third memory insulator 7. Similarly, the planar shapes of the insulators 9 are round annular shapes that surround the third memory insulator 7. Each interconnect 8 includes a barrier metal layer 8a that is an example of a first interconnect layer and an interconnect material layer 8b that is an example of a second interconnect layer. For example, the insulators 9 are silicon oxide films. The interconnects 8 function as word lines (control electrodes) of each memory element ME. Each memory element ME includes several tens of interconnects 8, for example.

The barrier metal layer 8a of each interconnect 8 is formed on the side face of the third memory insulator 7, and has an upper face that is in contact with the insulator 9 provided above the barrier metal layer 8a, and a lower face that is in contact with the insulator 9 provided under the barrier metal layer 8a. The lower face of the barrier metal layer 8a of the lowermost interconnect 8 is in contact with the inter layer dielectric 2 provided under the barrier metal layer 8a, instead of the insulator 9 provided under the barrier metal layer 8a. Examples of the barrier metal layer 8a are a titanium nitride (TiN) layer, a tantalum nitride (TaN) layer, a tungsten nitride (WN) layer and the like.

The interconnect material layer 8b of each interconnect 8 is formed on the side face of the barrier metal layer 8a, and has an upper face that is in contact with the insulator 9 provided above the interconnect material layer 8b, and a lower face that is in contact with the insulator 9 provided under the interconnect material layer 8b. The lower face of the interconnect material layer 8b of the lowermost interconnect 8 is in contact with the inter layer dielectric 2 provided under the interconnect material layer 8b, instead of the insulator 9 provided under the interconnect material layer 8b. Examples of the interconnect material layer 8b are a nickel (Ni) layer, a cobalt (Co) layer, a tungsten (W) layer and the like.

Reference character Wa denotes the thickness of the barrier metal layer 8a in a radial direction from the central axis of each memory element ME. Reference character Wb denotes the thickness of the interconnect material layer 8b in the radial direction from the central axis of each memory element ME. This radial direction is an example of a first direction of the disclosure. In each interconnect 8 of the present embodiment, the thickness Wb of the interconnect material layer 8b in the radial direction is set larger than the thickness Wa of the barrier metal layer 8a in the radial direction (Wb>Wa).

Reference character T denotes the thickness of the barrier metal layer 8a and the interconnect material layer 8b in each interconnect 8 in the Z direction. The Z direction is an example of a second direction of the disclosure. As described above, the barrier metal layer 8a and the interconnect material layer 8b are both in contact with the insulator 9 provided above these layers 8a and 8b and the insulator 9 (or the inter layer dielectric 2) provided under these layers 8a and 8b. Therefore, in each interconnect 8 of the present embodiment, the thickness of the barrier metal layer 8a in the Z direction and the thickness of the interconnect material layer 8b in the Z direction are set at the same value T.

Here, the volume of the barrier metal layer 8a in each interconnect 8 is denoted by Va, and the volume of the interconnect material layer 8b in each interconnect 8 is denoted by Vb. In the present embodiment, the volume Vb is desirably set larger than the volume Va (Vb>Va), which makes the ratio of the interconnect material layer 8b in each interconnect 8 higher than the ratio of the barrier metal layer 8a in each interconnect 8.

The inter layer dielectric 10 is formed on the inter layer dielectric 2 around the memory elements ME. An example of the inter layer dielectric 10 is a silicon oxide film. The inter layer dielectric 10 may be a stacked film including plural insulators. The semiconductor device in the present embodiment may include a plug interconnect that penetrates the inter layer dielectric 10 and is electrically connected to a diffusion layer in the substrate 1 or to an interconnect in the inter layer dielectric 2.

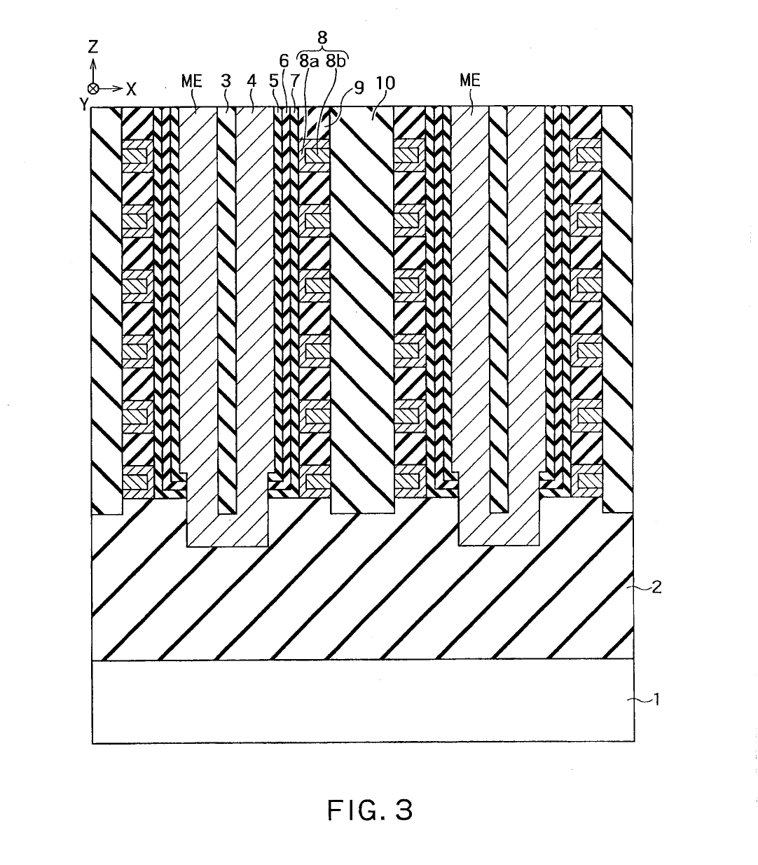

FIG. 3 is a cross sectional view showing a structure of a semiconductor device of a comparative example of the first embodiment.

A barrier metal layer 8a in the comparative example is formed on the side face of the third memory insulator 7. In the comparative example, the lower face of the insulator 9 provided above the barrier metal layer 8a and the upper face of the insulator 9 (or the inter layer dielectric 2) provided under the barrier metal layer 8a is covered with the barrier metal layer 8a. As a result, the interconnect material layer 8b in the comparative example is not in contact with the lower face of the insulator 9 provided above the interconnect material layer 8b and the upper face of the insulator 9 (or the inter layer dielectric 2) provided under the interconnect material layer 8b.

In the comparative example, if the Z directional thickness of each interconnect 8 is reduced, the ratio of the barrier metal layer 8a in each interconnect 8 becomes higher. The reason is that the reduced thickness of each interconnect 8 narrows down the gap between the barrier metal layer 8a on the lower face of the insulator 9 and the barrier metal layer 8a on the upper face of the insulator 9 (or the inter layer dielectric 2), which reduces a space for embedding the interconnect material layer 8b. As a result, the reduced film thickness of each interconnect 8 increases the resistance of the interconnects 8 in the comparative example.

In contrast, the barrier metal layer 8a and the interconnect material layer 8b in the present embodiment are both in contact with the lower face of the insulator 9 provided above these layers 8a and 8b, and the upper face of the insulator 9 (or the inter layer dielectric 2) provided under these layers 8a and 8b. Therefore, it is possible in the present embodiment to reduce the Z directional thickness of each interconnect 8 without increasing the ratio of the barrier metal layer 8a in each interconnect 8. The reason is that the volume Va of the barrier metal layer 8a can be reduced at almost the same rate as the reduction rate of the thickness of the interconnects 8. For example, if the thickness of the interconnects 8 is reduced by one-half with the thickness Wa of the barrier metal layer 8a and the thickness Wb of the interconnect material layer 8b unchanged, the volume Va of the barrier metal layer 8a is also reduced by almost one-half, and the volume Vb of the interconnect material layer 8b is thereby also reduced by almost one-half. As a result, the ratio of the barrier metal layer 8a in each interconnect 8 varies little even when the thickness of the interconnects 8 is reduced by one-half. Therefore, the present embodiment makes it possible to reduce the thickness of the interconnects 8 while preventing the resistance of the interconnects 8 from being increased.

Also, the thickness Wb of the interconnect material layer 8b is set larger than the thickness Wa of the barrier metal layer 8a in the present embodiment. In addition, the volume Vb of the interconnect material layer 8b is set larger than the volume Va of the barrier metal layer 8a in the present embodiment. Therefore, the present embodiment can make the ratio of the barrier metal layer 8a in each interconnect 8 be small and can therefore reduce the resistance of the interconnects 8.

### (2) Method of Manufacturing Semiconductor Device of First Embodiment

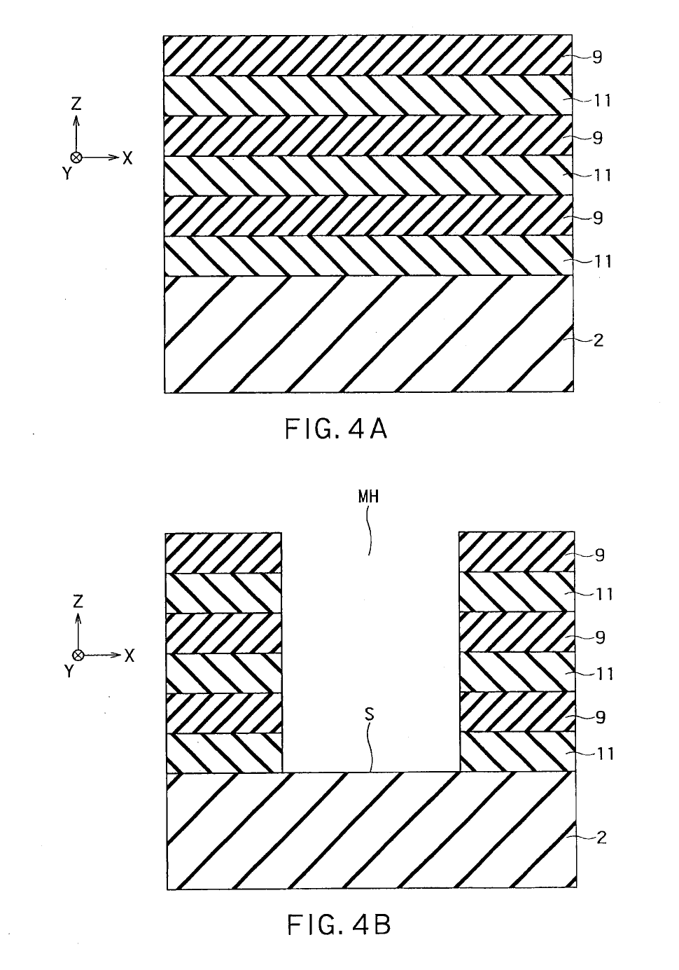

FIGS. 4A to 9B are cross sectional views showing a method of manufacturing the semiconductor device of the first embodiment.

First, an inter layer dielectric 2 is formed on a substrate 1 (not shown), and plural sacrificial films 11 and plural insulators 9 are alternately formed on the inter layer dielectric 2 (FIG. 4A). The sacrificial films 11 are an example of plural first films of the disclosure. The sacrificial films 11 are silicon nitride films, for example. The insulators 9 are silicon oxide films, for example.

Next, a memory hole MH is formed by lithography and etching to penetrate the sacrificial films 11 and the insulators 9 to reach the inter layer dielectric 2 (FIG. 4B). The memory hole MH is an example of an opening of the disclosure. Reference character S denotes the bottom face of the memory hole MH. Although plural memory holes MH are formed in this process, FIG. 4A shows one of these memory holes MH.

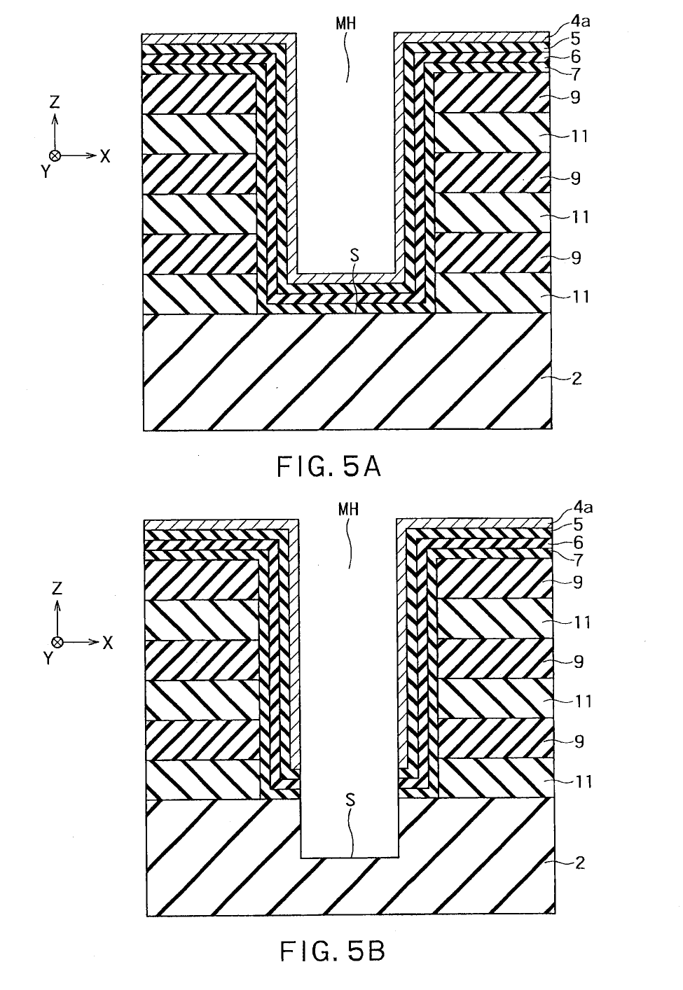

Next, a third memory insulator 7, a charge storing layer 6, a second memory insulator 5, and a first layer 4a of a semiconductor layer 4 are sequentially formed on the whole surface of the substrate 1 (FIG. 5A). As a result, the third memory insulator 7, the charge storing layer 6, the second memory insulator 5 and the first layer 4a are sequentially formed on the side face and the bottom face S of the memory hole MH. An example of the first layer 4a is an amorphous silicon layer.

Next, the third memory insulator 7, the charge storing layer 6, the second memory insulator 5 and the first layer 4a are removed from the bottom face S of the memory hole MH by lithography and etching (FIG. 5B). As a result, the bottom face S of the memory hole MH is exposed again. Furthermore, the inter layer dielectric 2 is also etched, which makes the bottom face S of the memory hole MH lower than the uppermost face of the inter layer dielectric 2.

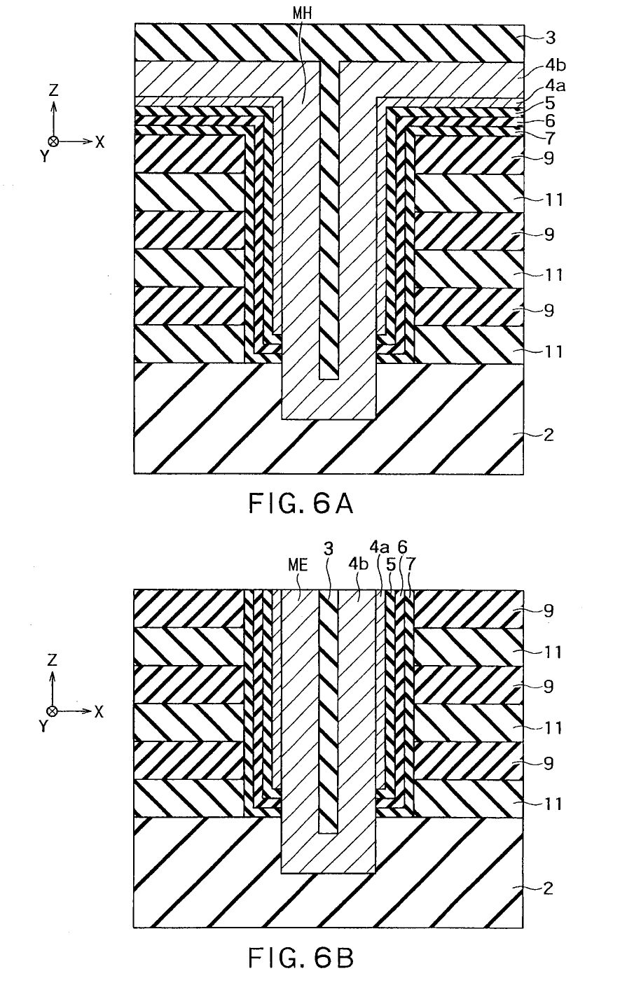

Next, a second layer 4b of the semiconductor layer 4, and a first memory insulator 3 are sequentially formed on the whole surface of the substrate 1 (FIG. 6A). As a result, the second layer 4b is formed on the bottom face S of the memory hole MH, and is formed on the side face of the memory hole MH through the third memory insulator 7, the charge storing layer 6, the second memory insulator 5 and the first layer 4a. Furthermore, the memory hole MH is completely filled with the first memory insulator 3. An example of the second layer 4b is an amorphous silicon layer.

Next, the surfaces of the first memory insulator 3 and the semiconductor layer 4 are planarized by chemical mechanical polishing (CMP) (FIG. 6B). This planarization is continued until the uppermost insulator 9 is exposed. Thereafter, the semiconductor layer 4 is crystallized into a monocrystalline silicon layer by annealing the substrate 1.

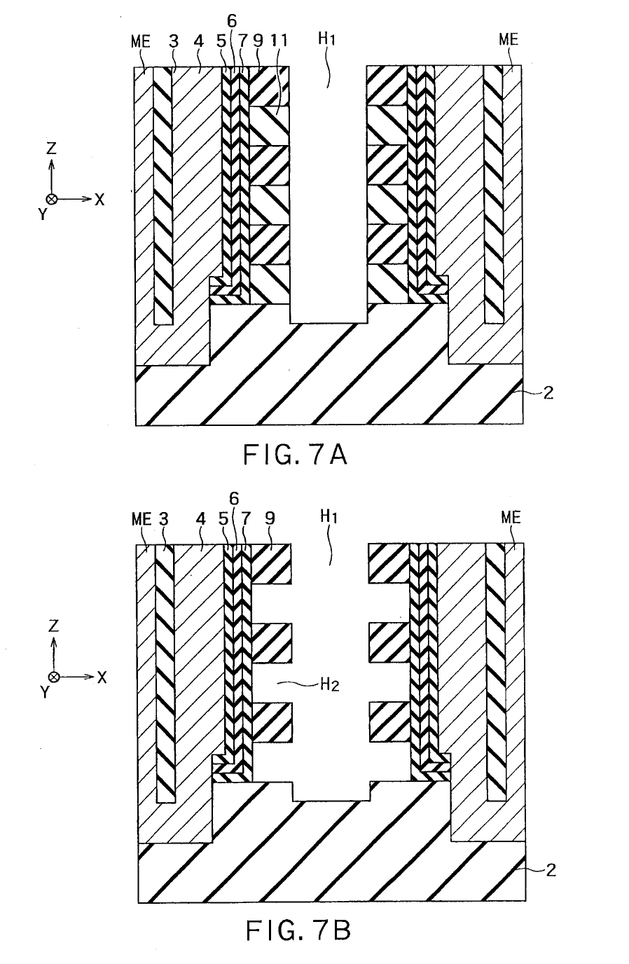

While FIGS. 4A to 6B show the cross sections of one memory element ME, FIGS. 7A to 9B show the cross sections of two memory elements ME.

Next, an opening H₁ is formed by lithography and etching to penetrate the sacrificial films 11 and the insulators 9 to reach the inter layer dielectric 2 (FIG. 7A). In this process, the inter layer dielectric 2 is also etched, and therefore the bottom face of the opening H₁ is lowered below the uppermost face of the inter layer dielectric 2. The opening H₁ is formed in a region where the inter layer dielectric 10 in FIG. 1 is to be formed.

Next, the sacrificial films 11 are removed by selective etching while the insulators 9 are left (FIG. 7B). As a result, plural concave portions H₂ are formed between the insulators 9. The concave portions H₂ are also formed between the lowermost insulator 9 and the inter layer dielectric 2. By this etching, the side face of the third memory insulator 7 is exposed in the concave portions H₂.

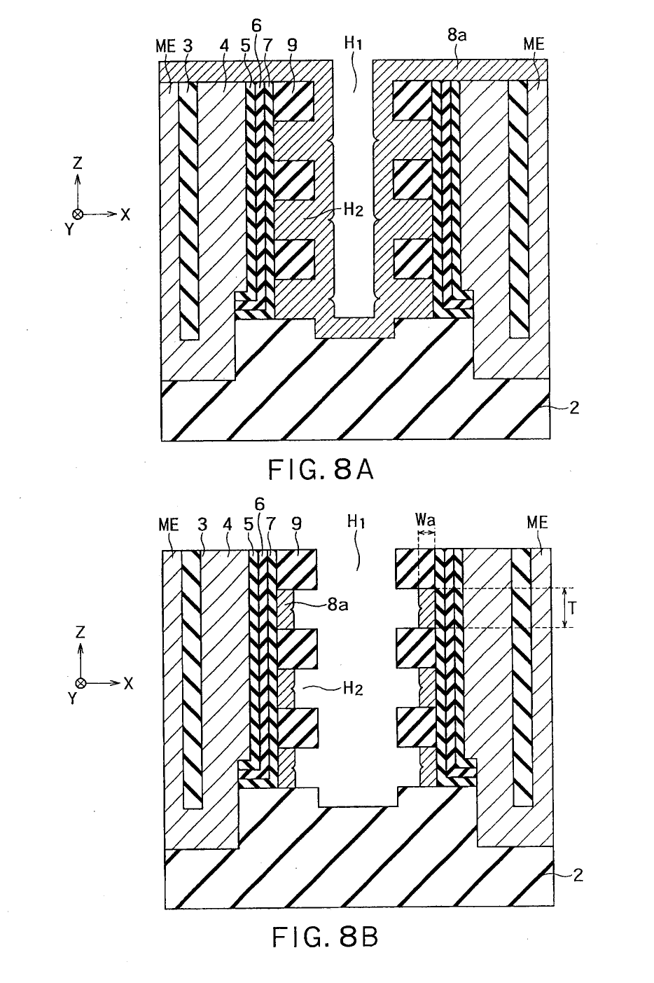

Next, the barrier metal layer 8a is formed on the whole surface of the substrate 1 (FIG. 8A). As a result, the barrier metal layer 8a is formed on the side face of the third memory insulator 7 in the concave portions H₂. This process is performed such that the concave portions H₂ are completely filled with the barrier metal layer 8a. Examples of the barrier metal layer 8a are a TiN layer, a TaN layer, a WN layer and the like.

Next, the barrier metal layer 8a is etched by wet etching (FIG. 8B). This process is performed such that the barrier metal layer 8a in the concave portions H₂ is partially removed. By wet etching, the etching of the barrier metal layer 8a can be progressed isotropically, which makes it possible to isotropically recess the surfaces of the barrier metal layers 8a in the concave portions H₂. As a result, a barrier metal layer 8a is formed in each concave portion H₂ such that the barrier metal layer 8a is in contact with a portion of the lower face of the insulator 9 provided above it and a portion of the upper face of the insulator 9 (or the inter layer dielectric 2) provided under it. The remaining upper face and lower face in each concave portion H₂ are exposed from the barrier metal layer 8a. Through this process, the barrier metal layer 8a in each concave portion H₂ is made to have the thickness Wa in the radial direction and to have the thickness T in the Z direction. Through this process, the barrier metal layer 8a in each concave portion H₂ is also made to have the volume Va.

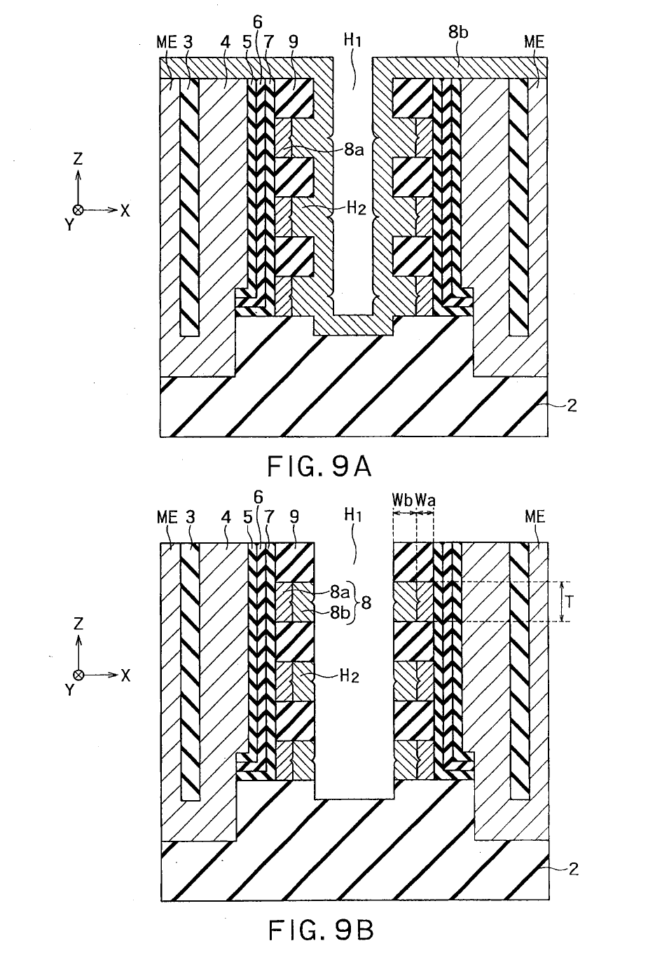

Next, an interconnect material layer 8b is formed on the whole surface of the substrate 1 (FIG. 9A). As a result, the interconnect material layer 8b is formed on the side faces of the barrier metal layers 8a in the concave portions H₂. This process is performed such that the concave portions H₂ are completely filled with the barrier metal layers 8a and the interconnect material layer 8b. Examples of the interconnect material layer 8b are a Ni layer, a Co layer, a W layer and the like.

Next, the interconnect material layer 8b is etched by wet etching (FIG. 9B). This process is performed such that the interconnect material layer 8b outside the concave portions H₂ is removed, and the interconnect material layers 8b in the concave portions H₂ are left. As a result, an interconnect material layer 8b is formed in each concave portion H₂ such that the interconnect material layer 8b is in contact with a portion of the lower face of the insulator 9 provided above it and a portion of the upper face of the insulator 9 (or the inter layer dielectric 2) provided under it. Through this process, the interconnect material layer 8b in each concave portion H₂ is made to have the thickness Wb in the radial direction and to have the thickness T in the Z direction. Through this process, the interconnect material layer 8b in each concave portion H₂ is also made to have the volume Vb.

In this way, an interconnect 8 including the barrier metal layer 8a and the interconnect material layer 8b is formed in each concave portion H₂. Thereafter, the inter layer dielectric 10 is formed in the opening H₁. Furthermore, various inter layer dielectrics, interconnect layers, plug layers and the like are formed on the substrate 1. In this way, the semiconductor device in the present embodiment is manufactured.

In the process of FIG. 8B, dry etching for reducing the thickness of the barrier metal layer 8a may be performed before the wet etching of the barrier metal layer 8a. Similarly, in the process of FIG. 9B, dry etching for reducing the thickness of the interconnect material layer 8b may be performed before the wet etching of the interconnect material layer 8b.

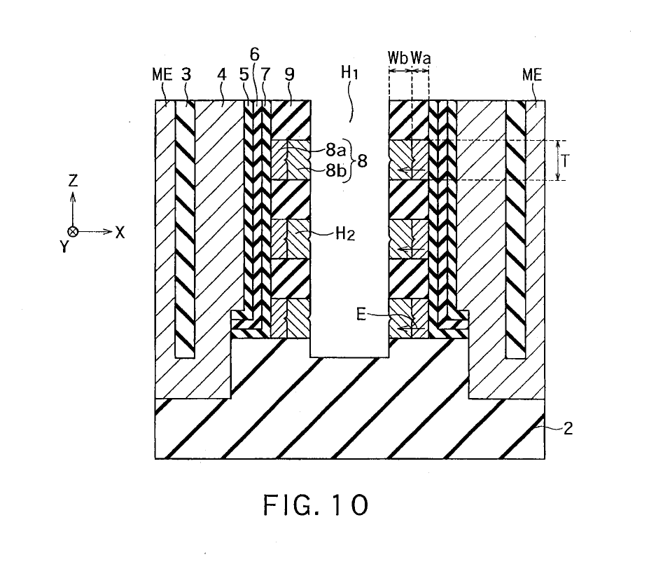

FIG. 10 is a cross sectional view showing a method of manufacturing a semiconductor device of a modification of the first embodiment.

In the present embodiment, instead of forming the interconnect material layers 8b through the processes of the FIG. 9A and FIG. 9B, the interconnect material layers 8b may be formed through the process of FIG. 10. In the process of FIG. 10, as shown by arrows E, an interconnect material layer 8b is formed in each concave portion H₂ by selectively growing the interconnect material layer 8b on the side face of the barrier metal layer 8a in the concave portion H₂. This makes it possible to omit the etching process illustrated in FIG. 9B. An example of the interconnect material layer 8b in the present modification is a tungsten (W) layer.

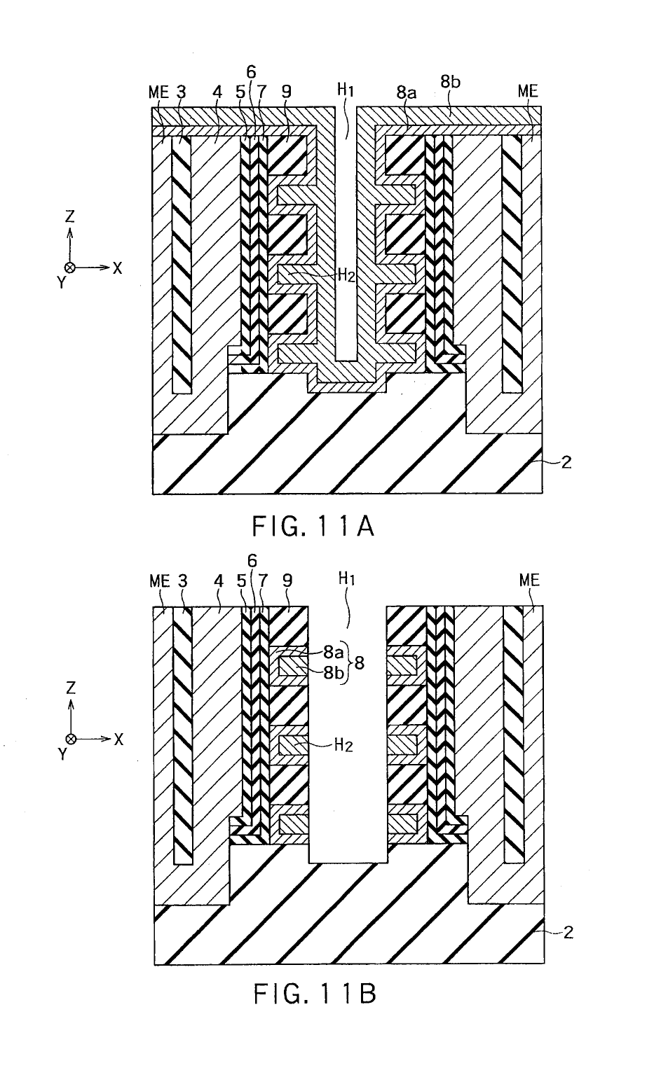

FIGS. 11A and 11B are cross sectional views showing a method of manufacturing the semiconductor device of the comparative example of the first embodiment.

In the comparative example, the processes of FIGS. 11A and 11B are performed instead of the processes of FIGS. 8A to 9B. In the process of FIG. 11A, a barrier metal layer 8a and an interconnect material layer 8b are sequentially formed on the whole surface of the substrate 1. In the process of FIG. 11B, the barrier metal layer 8a and the interconnect material layer 8b outside the concave portions H₂ are removed by wet etching. In this way, the interconnects 8 having the structure shown in FIG. 3 are formed.

In the comparative example, if the Z directional thickness of each interconnect 8 is reduced, the ratio of the barrier metal layer 8a in each interconnect 8 becomes higher, which increases the resistance of the interconnects 8. Furthermore, when the barrier metal layer 8a is formed in the concave portions H₂, the opening areas of the concave portions H₂ become smaller, which makes it difficult to embed the interconnect material layer 8b in the concave portions H₂.

In contrast, the present embodiment makes it possible to reduce the Z directional thickness of each interconnect 8 without increasing the ratio of the barrier metal layer 8a in each interconnect 8. Therefore, the present embodiment makes it possible to reduce the Z directional thickness of each interconnect 8 while suppressing the increase of the resistance of the interconnects 8. Furthermore, since it is possible to form the barrier metal layers 8a in the concave portions H₂ without reducing the opening areas of the concave portions H₂, the present embodiment makes it possible to easily embed the interconnect material layers 8b in the concave portions H₂.

As described above, the present embodiment makes it possible to suppress the increase of the resistance of the interconnects 8 owing to the reduction of the thickness of the interconnects 8.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a substrate;
a semiconductor layer provided on the substrate; and
plural insulators and plural interconnects alternately provided on a side face of the semiconductor layer,
wherein each of the interconnects comprises:
a first interconnect layer provided on the side face of the semiconductor layer, and having an upper face that is in contact with one of the insulators and a lower face that is in contact with one of the insulators; and
a second interconnect layer provided on a side face of the first interconnect layer, and having an upper face that is in contact with one of the insulators and a lower face that is in contact with one of the insulators.

2. The device of claim 1, wherein a thickness of the second interconnect layer in a first direction that is parallel to a surface of the substrate is larger than a thickness of the first interconnect layer in the first direction.

3. The device of claim 1, wherein a thickness of the second interconnect layer in a second direction that is perpendicular to a surface of the substrate is equal to a thickness of the first interconnect layer in the second direction.

4. The device of claim 1, wherein a volume of the second interconnect layer in each interconnect is larger than a volume of the first interconnect layer in each interconnect.

5. The device of claim 1, wherein the insulators and the interconnects have annular planar shapes that surround the semiconductor layer.

6. The device of claim 1, wherein the first interconnect layer contains at least one of titanium, tantalum and tungsten.

7. The device of claim 1, wherein the second interconnect layer contains at least one of nickel, cobalt and tungsten.

8. The device of claim 1, further comprising:
a first insulator provided on the side face of the semiconductor layer;
a charge storing layer provided on a side face of the first insulator; and
a second insulator provided on a side face of the charge storing layer,
wherein the insulators and the interconnects are alternately provided on a side face of the second insulator.

9. The device of claim 8, wherein the first insulator, the charge storing layer and the second insulator have annular planar shapes that surround the semiconductor layer.

10. A method of manufacturing a semiconductor device, comprising:
alternately forming plural insulators and plural first films on a substrate;
forming an opening in the insulators and the first films;
forming a semiconductor layer in the opening;
removing, after the semiconductor layer is formed, the first films to form plural concave portions between the insulators;
forming first interconnect layers on a side face of the semiconductor layer in the concave portions, each of the first interconnect layers being in contact with an upper face of one of the insulators and a lower face of one of the insulators; and
forming second interconnect layers on side faces of the first interconnect layers in the concave portions to form plural interconnects including the first and second interconnect layers, each of the second interconnect layers being in contact with an upper face of one of the insulators and a lower face of one of the insulators.

11. The method of claim 10, wherein the first interconnect layers are formed by forming the first interconnect layers in the concave portions and partially removing the first interconnect layers in the concave portions.

12. The method of claim 11, wherein the first interconnect layers in the concave portions are partially removed such that upper faces and lower faces of the insulators are exposed.

13. The method of claim 10, wherein the second interconnect layers are formed by selectively growing the second interconnect layers on the side faces of the first interconnect layers.

14. The method of claim 10, wherein the interconnects are formed such that a thickness of the second interconnect layers in a first direction that is parallel to a surface of the substrate is larger than a thickness of the first interconnect layers in the first direction.

15. The method of claim 10, wherein the interconnects are formed such that a thickness of the second interconnect layers in a second direction that is perpendicular to a surface of the substrate is equal to a thickness of the first interconnect layers in the second direction.

16. The method of claim 10, wherein the interconnects are formed such that a volume of a second interconnect layer in each interconnect is larger than a volume of a first interconnect layer in each interconnect.

17. The method of claim 10, wherein the first interconnect layers contain at least one of titanium, tantalum and tungsten.

18. The method of claim 10, wherein the second interconnect layers contain at least one of nickel, cobalt and tungsten.

19. The method of claim 10, further comprising sequentially forming a second insulator, a charge storing layer and a first insulator on a side face of the opening,
wherein the semiconductor layer is formed on the side face of the opening through the second insulator, the charge storing layer and the first insulator.

20. The method of claim 19, wherein the first interconnect layers are formed on a side face of the second insulator in the concave portions.
